(19) United States
(12) Patent Application Publication
(10) Pub. No.: US 2023/0197575 A1
(43) Pub. Date: Jun. 22, 2023

(54) DIE ATTACH ADHESIVE-READY LEAD FRAME DESIGN

(71) Applicant: Texas Instruments Incorporated, Dallas, TX (US)

(72) Inventors: John Carlo Molina, Limay (PH); Ernesto P. Rafael, Jr., Pampanga (PH); Dolores B. Milo, Baguio City (PH)

(21) Appl. No.: 17/711,668

(22) Filed: Apr. 1, 2022

Related U.S. Application Data
(60) Provisional application No. 63/291,946, filed on Dec. 20, 2021.

(51) Int. Cl. H01L 23/495; H01L 21/48

(52) U.S. Cl. CPC H01L 23/49513; H01L 21/4828; H01L 23/49548; H01L 21/4842; H01L 24/48

(57) ABSTRACT

An integrated circuit package includes a die attach pad and a plurality of conductors formed from a lead frame material. A cavity is formed in a top surface of the die attach pad. A die attach adhesive is disposed within the cavity. A top surface of the die attach adhesive is flush with the top surface of the die attach pad. A semiconductor die is mounted on the die attach pad using the die attach adhesive. The semiconductor die is electrically connected to the plurality of conductors through a set of bond wires. A bottom surface of the semiconductor die is coplanar with the top surface of the die attach pad. A molding compound covers portions of the lead frame, the semiconductor die, and the set of bond wires.

### CROSS REFERENCE TO RELATED APPLICATIONS

This application claims the benefit of the filing date of U.S. Provisional Patent Application No. 63/291,946, which was filed Dec. 20, 2021, the disclosure of which is hereby incorporated by reference herein in its entirety.

### BACKGROUND

A semiconductor package is a metal, plastic, glass, or ceramic casing containing one or more semiconductor dies or components. It is well known that packaging plays a fundamental role in the operation and performance of a component such as a semiconductor integrated circuit (IC) or die. Traditional methods of fabricating a semiconductor die package typically involve attaching semiconductor dies to a substrate having a plurality of electrical conductors or conductive fingers, wherein the attaching comprises suitable application of a select die attach material. The select die attach material is applied by a device manufacturer to a substrate, such as a lead frame that is provided by a separate vendor. The die attach material is cured, followed by wire-bonding bond pads of the semiconductor die to electrical conductors of the substrate using bond wires. An encapsulant material is applied to the structure covering at least a portion of the die and at least a portion of the substrate including the bond wires.

### SUMMARY

An integrated circuit package includes a lead frame with a pre-applied die attach adhesive that replaces conventional epoxy dispensed die pads. In one example, a die attach film is attached to the lead frame after etching through a tape lamination process, such as using pre-cut tape designs based on die pad size. In another example, an adhesive is applied to the lead frame such as by spraying or screen printing onto a cavity produced through an additional etching process, which allows for the adhesive to be flush with the die pad.

In one example, a semiconductor package comprises a lead frame including a die attach pad and a plurality of conductors. A cavity is formed in a top surface of the die attach pad. A die attach material is disposed within the cavity. A semiconductor die is mounted on the die attach pad using the die attach material. The semiconductor die is electrically connected to the plurality of conductors through a set of bond wires. A molding structure covers portions of the lead frame, the semiconductor die, and the set of bond wires. A top surface of the die attach material may be flush with the top surface of the die attach pad. A bottom surface of the semiconductor die may be coplanar with the top surface of the die attach pad. A rim of the die attach material may be positioned on the top surface of the die attach pad and adjacent to all sides of the semiconductor die.

In another example, an integrated circuit package comprises a die attach pad and a plurality of conductors formed from a lead frame material. A cavity is formed in a top surface of the die attach pad. A die attach adhesive is disposed within the cavity. A top surface of the die attach adhesive is flush with the top surface of the die attach pad. A semiconductor die is mounted on the die attach pad using the die attach adhesive. The semiconductor die is electrically connected to the plurality of conductors through a set of bond wires. A bottom surface of the semiconductor die is coplanar with the top surface of the die attach pad. A molding compound covering portions of the lead frame, the semiconductor die, and the set of bond wires. A rim of die attach material may be located on the top surface of the die attach pad and adjacent to all sides of the semiconductor die.

In an example method for manufacturing a semiconductor package, steps include providing a lead frame having a plurality of die attach pads, wherein each die attach pad has a top surface with a pre-installed layer of die attach material; adhering a semiconductor device to each die attach pad using the die attach material; attaching wire bonds from contacts on each semiconductor device to leads on the lead frame; and covering at least a portion of the semiconductor devices, die attach pads, die adhesive material, wire bonds, and leads with a mold compound. A cavity may be etched into a top surface of each of the die attach pads on the lead frame, and the pre-installed layer of die attach material disposed within each of the cavities. The method may comprise activating the die attach material using heat or UV energy prior to adhering the semiconductor devices. The method may comprise removing a protective material from the lead frame prior to adhering the semiconductor devices.

### BRIEF DESCRIPTION OF THE DRAWINGS

Having thus described the invention in general terms, reference will now be made to the accompanying drawings, wherein:

FIG. 1 is a top view of a portion of a conductive lead frame strip.

FIG. 2 illustrates a detailed view of a portion of a conductive lead frame strip from FIG. 1, such as for a Quad Flat No-lead (QFN) package.

FIG. 3 is a side view of an integrated circuit package that has been singulated from a lead frame sheet, such as the portion shown in FIG. 2.

FIGS. 4A-C illustrate steps for the manufacture of a lead frame strip having pre-applied die attach film.

FIGS. 5A-E illustrate steps for the manufacture of a lead frame strip having pre-applied die attach film.

FIG. 6 illustrates an alternative example of a premolded lead frame sheet.

FIG. 7 is a flowchart illustrating steps of an example process for manufacturing a semiconductor package.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

Corresponding numerals and symbols in the different figures generally refer to corresponding parts, unless otherwise indicated. The figures are not necessarily drawn to scale. In the drawings, like reference numerals refer to like elements throughout, and the various features are not necessarily drawn to scale. In the following discussion and in the claims, the terms “including,” “includes,” “having,” “has,” “with,” or variants thereof are intended to be inclusive in a manner similar to the term “comprising,” and thus should be interpreted to mean “including, but not limited to . . . ” Also, the terms “coupled,” “couple,” and/or or “couples” is/are intended to include indirect or direct electrical or mechanical connection or combinations thereof. For example, if a first device couples to or is electrically coupled with a second device that connection may be through a direct electrical connection, or through an indirect electrical connection via one or more intervening devices and/or connections. Terms such as “top,” “bottom,” “front,” “back,” “over,” “above,” “under,” “below,” and such, may be used in this disclosure. These terms should not be construed as limiting the position or orientation of a structure or element but should be used to provide spatial relationship between structures or elements.

The term “semiconductor device” is used herein. A semiconductor device can be a discrete semiconductor device such as a bipolar transistor, a few discrete devices such as a pair of power FET switches fabricated together on a single semiconductor die, or a semiconductor die can be an integrated circuit with multiple semiconductor devices such as the multiple capacitors in an A/D converter. The semiconductor device can include passive devices such as resistors, inductors, filters, sensors, or active devices such as transistors. The semiconductor device can be an integrated circuit with hundreds or thousands of transistors coupled to form a functional circuit, for example a microprocessor or memory device. The semiconductor device may also be referred to herein as a “semiconductor die.”

The term “integrated circuit package” is used herein. An integrated circuit package has at least one semiconductor device electrically coupled to terminals and has a package body that protects and covers the semiconductor device. In some arrangements, multiple semiconductor devices can be packaged together. For example, a power field effect transistor (FET) semiconductor device and a second semiconductor device (such as a gate driver die or a controller die) can be packaged together to from a single packaged electronic device. Additional components such as passives can be included in the packaged electronic device. The semiconductor device is mounted with a package substrate that provides conductive leads. A portion of the conductive leads form the terminals for the packaged device. In wire bonded integrated circuit packages, bond wires couple conductive leads of a package substrate to bond pads on the semiconductor device. The integrated circuit package can have a package body formed by a thermoset epoxy resin mold compound in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation. These exposed lead portions form the terminals for the integrated circuit package. The integrated circuit package may also be referred to herein as a “semiconductor package” or a “sensor package.”

A package substrate is a substrate arranged to receive a semiconductor die and to support the semiconductor die in a completed semiconductor device package. Package substrates useful with the arrangements include conductive lead frames, which can be formed from copper, aluminum, stainless steel, steel, and alloys such as Alloy 42 and copper alloys. The lead frames can include a die pad with a die side surface for mounting a semiconductor die, and conductive leads arranged near and spaced from the die pad for coupling to bond pads on the semiconductor die using wire bonds, ribbon bonds, or other conductors. In example arrangements, a heat slug is attached to the package substrate, and the heat slug has a die mounting area for mounting semiconductor devices. The lead frames can be provided in strips or arrays. The conductive lead frames can be provided as a panel with strips or arrays of unit device portions in rows and columns. Semiconductor devices can be placed on respective unit device portions within the strips or arrays. A semiconductor device can be placed on a die mount area for each packaged semiconductor device. Die attach or die adhesive can be used to mount the semiconductor devices. In wire bonded packages, bond wires can couple bond pads on the semiconductor devices to the leads of the lead frames. The lead frames may have plated portions in areas designated for wire bonding, for example silver, nickel, gold, or palladium plating can be used. After the bond wires are in place, a portion of the package substrate, the semiconductor device, and at least a portion of the die pad can be covered with a protective material such as a mold compound. More than one semiconductor device can be mounted to a package substrate for each unit.

The term “die attach pad” is used herein. A die attach pad is portion of a metal lead frame that is adapted for mounting a semiconductor device or semiconductor die. The semiconductor device may be mounted on the die attach pad by a layer of die attachment material that electrically and physically connects the semiconductor device to the lead frame.

The term “bond pad” is used herein. A bond pad is an area on a semiconductor device that allows the device to be electrically coupled to external circuits, such as by wire bonding to a lead frame or printed circuit board. The bond pad may be formed of a variety of materials, such as aluminum, gold, or copper. Additionally, the bond pad may take a variety of configurations.

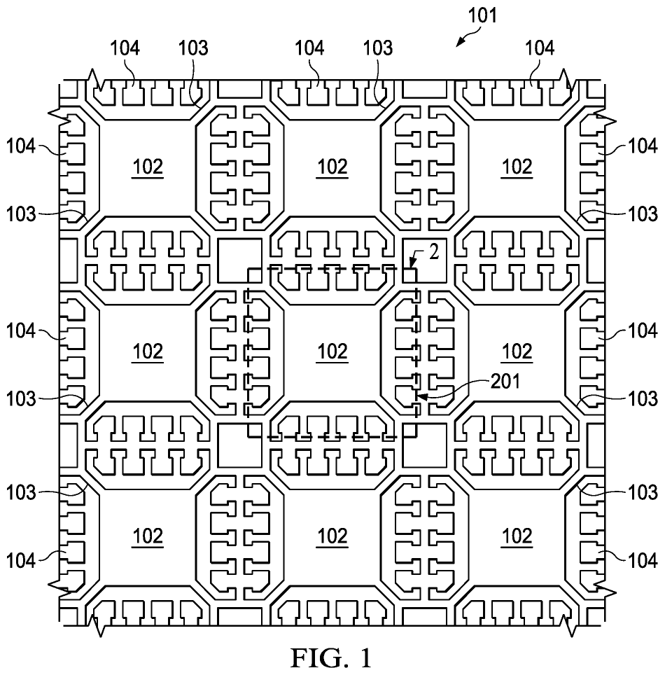

FIG. 1 is a top view of a portion of a conductive lead frame strip 101, which can be formed from copper, aluminum, stainless steel, steel, and alloys such as Alloy 42 and copper alloys. Lead frame strip 101 has die attach pad (DAP) portions 102 that are held in place and spaced apart by various tie bar portions 103. The DAP portions have a die side surface for mounting a semiconductor die. The tie bar portions 103 may include conductive leads 104 arranged near and spaced from the DAP portions 102. The conductive leads 104 are for coupling to bond pads on the semiconductor dies using wire bonds, ribbon bonds, or other conductors. Conductive leads may be plated for improved wire bonding, for example silver, nickel, gold, or palladium plating can be used. Lead frame strip 101 may be provided, for example, by a lead frame supplier to be used in the manufacture of a semiconductor device. The lead frames can be provided in strips or arrays.

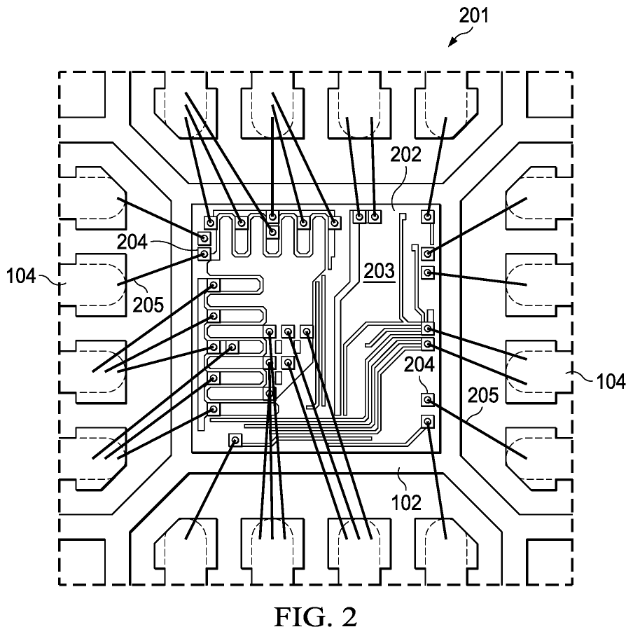

FIG. 2 illustrates a detailed view of a portion 201 of conductive lead frame strip 101 from FIG. 1 such as for a Quad Flat No-lead (QFN) package. A semiconductor die 202 has been mounted on DAP portion 102. The semiconductor die 202 has an active surface 203 with a number of bond pads 204. Bonds pads 204 are coupled to conductive leads 104 using bond wires 205, for example. The conductive lead frame 101 can be provided as a panel with strips or arrays of DAP portions 102 in rows and columns. Semiconductor devices 202 can be placed on respective DAP portions 102 within the strips or arrays. After the bond wires are in place, a portion of the package substrate, the semiconductor device, and at least a portion of the die attach pad can be covered with a protective material, such as a mold compound, and the lead frame strip 101 can be singulated into individual integrated circuit packages.

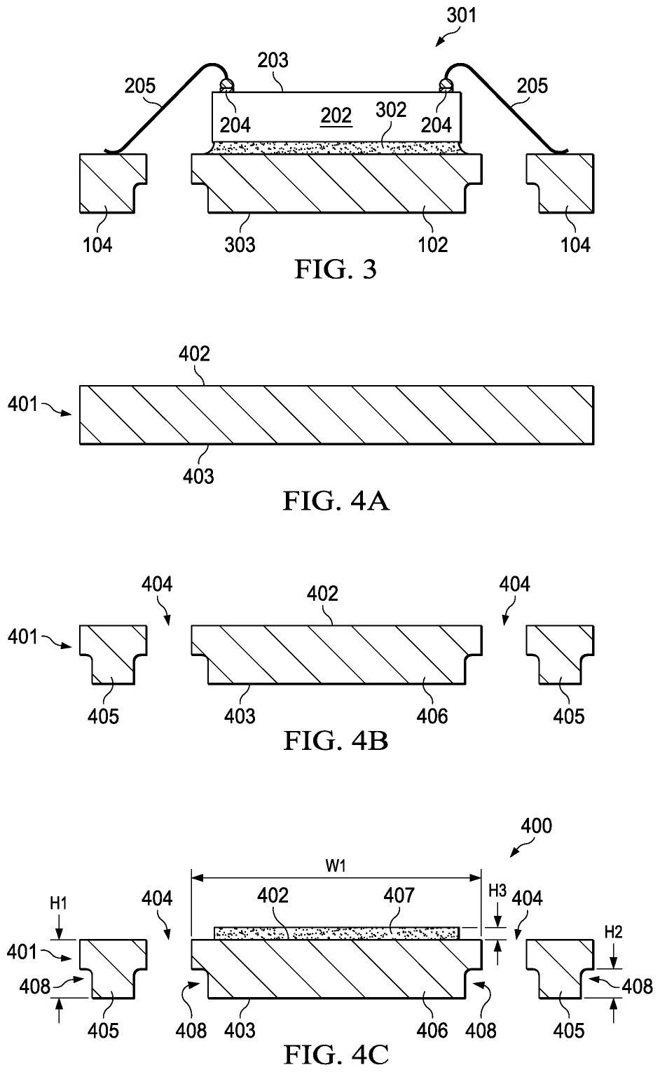

FIG. 3 is a side view of an integrated circuit package 301 that has been singulated from a lead frame sheet, such as portion 201 of FIG. 2. In the illustrated example, the semiconductor die 202 is large and nearly fills the area of DAP portion 102. A die attach adhesive 302 or a die attach film (DAF), can be used to mount the semiconductor device 202 on the DAP portion 102. Fillet and bleed require a minimum keep-out zone around semiconductor die 202. Devices having a semiconductor die area that is close to the die attach pad area have a tendency for epoxy contamination on the backside 302 of DAP portion due to the application of excessive epoxy material during the die attach process. Excess epoxy and bleed out can run over the edges of DAP portion 102 and flow on the backside 302 of lead frame 101.

In one example, to prevent the die attach from overflowing the die attach pad, a die attach film may be pre-applied to the die attach pad area during lead frame manufacture. FIGS. 4A-C illustrate steps for the manufacture of a lead frame strip having pre-applied die attach film. FIG. 4A illustrates a base lead frame material 401, such as a copper sheet, having a top surface 402 and a bottom surface 403. FIG. 4B illustrates the lead frame material 401 after an etching process. For example, a photoresist material, such as a dry film resist (DFR), is laminated on the top surface 402 and bottom surface 403 of the lead frame material 401. The photoresist material is irradiated, such as with a visible light laser, in the form of a desired lead frame pattern image. The photoresist material is then subjected to a developer that selectively dissolves any non-irradiated portion of the negative tone photoresist material or irradiated portion of the positive tone photoresist material thereby exposing some areas 404 of the lead frame material 401. The masked lead frame material 401 is then subjected to a wet or dry etching process. The areas 404 of the lead frame material 401 not covered by the mask are etched away. Those areas of the lead frame material 401 covered by the mask portions are unetched and remain after the etching process. These unetched portions form conductive lead regions 405 and die attach portion region 406.

FIG. 4C illustrates a die attach film 407, such as a fully cured epoxy, that has been attached to the die attach pad 406 after the etching process. The die attach film 407 may be applied using a tape lamination process, for example. Die attach film 407 may be a pre-cut tape with a design based on the size of die attach pad 406. The pre-cut tape 407 is applied to lead frame material 401 to create a lead frame sheet 400 that is ready for the die-attach process. Lead frame sheet 400 can be used in semiconductor device assembly without requiring a separate step of applying die attach in the assembly process. Instead, the assembly process can begin with a die mount step and proceed to wire bonding and molding. While this may result in an increase in lead frame cost due to an additional step of adding the die attach film, the die bond process will be simplified by eliminating an epoxy dispense step. The amount of die attach film 407 applied in FIG. 4C can be controlled during lead frame manufacturing so that the die attach film will not overflow the die attach pad 406 when a semiconductor device is mounted on the die attach pad 406 using the die attach film 407.

In one example, the die attach pad 406 has a width W1 of 3 mm, and lead frame material 401 has a thickness H1 of 0.2 mm. Connective leads 405 and die attach pad 406 have half-etched edges 408 with a thickness H2 of 0.1 mm. Die attach film 407 may have a thickness H3 of 0.02 mm.

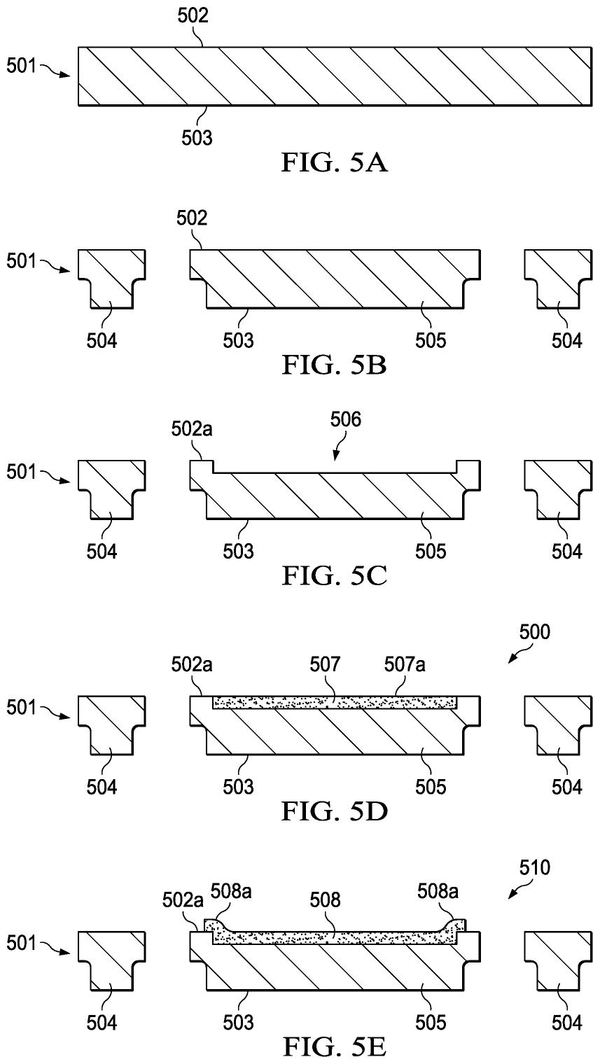

In another example, to prevent the die attach from overflowing the die attach pad, a die attach adhesive may be pre-applied to the die attach pad area during lead frame manufacture. FIGS. 5A-E illustrate steps for the manufacture of a lead frame strip having pre-applied die attach adhesive. FIG. 5A illustrates a base lead frame material 501, such as a copper sheet, having a top surface 502 and a bottom surface 503. FIG. 5B illustrates the lead frame material 501 after an etching process such as the one described in relation to FIG. 4B. The unetched portions form conductive lead regions 504 and die attach portion region 505.

FIG. 5C illustrates the results of a second etching step in which a cavity 506 is etched into the top surface 502a of die attach pad 505. The cavity 506 is then filled with a die attach adhesive 507 such as an epoxy applied by screen printing or spraying. FIG. 5D illustrates cavity 506 filled with die adhesive 507, which may be any appropriate adhesive used to attach a semiconductor chips to die attach pad 505. The die attach adhesive may be electrically insulating and/or thermally conductive. The depth of cavity 506 and the amount of die adhesive 507 may be selected so that the top surface 507a of the die adhesive 507 is flush with the top surface 502a of the die attach pad 505. The cavity 506 has a surface area defined by a length and width across the top surface 507a. The surface area of the cavity may be selected to be equal to a bottom surface of a semiconductor die. The surface area of the cavity may also be larger than the surface area of the bottom of the semiconductor die so that a portion of the die adhesive 507 will surround the semiconductor die when mounted on the lead frame sheet 500. Lead frame sheet 500 can be provided to semiconductor device manufacturer for package assembly without requiring a separate step of applying die attach.

The amount of die attach adhesive 507 applied in FIG. 5D can be controlled during lead frame manufacturing so that the die adhesive 507 will not overflow die attach pad 505 when a semiconductor device is mounted on die attach pad 505 using the die adhesive 507.

In one example, a lower overall package thickness may be achieved when a semiconductor die is mounted on die attach pad 505 using die adhesive 507 by controlling the depth of cavity 506 and the amount of die adhesive 507 deposited. The bottom surface of a semiconductor die that is attached to die attach pad 505 above cavity 506 will be flush with the top surface of the die attach pad 505. Cavity 506 and pre-applied die attach material 507 eliminates the need for a die attach layer that sits on top of die attach pad 505, such as layer 302 in FIG. 3.

FIG. 5E illustrates an alternative example of a lead frame sheet 510 in which a die adhesive 508 is used to fill cavity 506 and some die adhesive 508a overlaps the top surface 502a of die attach pad 505. In one example, a stencil or mask may be used when the die adhesive is sprayed or screen printed on die attach pad 505. The stencil or mask allows for the die adhesive 508 to fill cavity 506 and to partially overlap 508a the edges of the cavity 506. In this example, the die adhesive 508 is not flush with the top surface 502a of the die attach pad 505. The overlapping die adhesive 508 forms a ring or rim around cavity 506 on the top surface 502a. The amount of overlap 508a is controlled to prevent excess die adhesive 508 from overflowing the die attach pad 505 when a semiconductor die is mounted.

The lead frame examples 500 and 510 illustrated in FIGS. 5D and 5E provide opportunities for lower semiconductor package height due to the top 507a of the die attach adhesive 507 being generally coplanar with the top 502a of the die attach pad 502. Accordingly, a semiconductor die may be mounted with its bottom surface generally coplanar with the top 502a of the die attach pad 502.

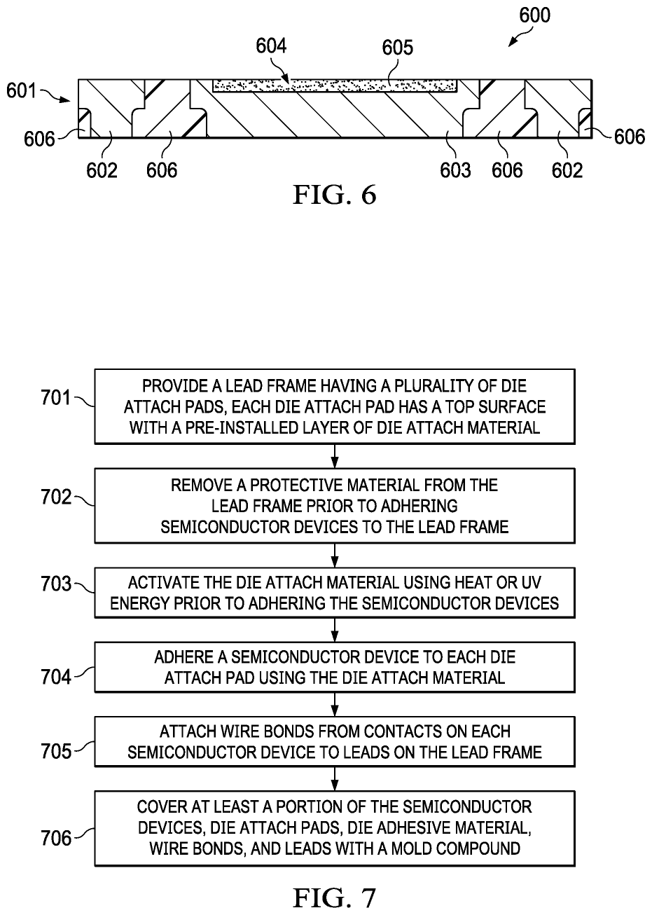

FIG. 6 illustrates a further alternative example of a premolded lead frame sheet 600. Lead frame sheet 600 has a lead frame material 601, such as copper or copper alloy, that has been etched to create conductive leads 602 and die attach pad 603. Die attach pad 603 has been further etched to create a cavity 604, which is filled with a die attach adhesive 605. Open areas of lead frame sheet 600 are then filled with a molding compound 606, such as an epoxy or plastic. In example lead frame sheet 600, mold compound 606 is applied so that the top and bottom surfaces of mold compound 606 are flush with the top and bottom surfaces of conductive lead 602, die attach pad 603, and die attach adhesive 605.

Premolded lead frame sheet 600 is similar to lead frame sheet 500 (FIG. 5D). In other examples, mold compound may also be applied to other lead frame sheets, such as lead frame sheet 400 (FIG. 4C) and lead frame sheet 510 (FIG. 5E).

Lead frame sheets having pre-applied die attach film or die attach adhesive can be provided by a lead frame manufacturer to a semiconductor device manufacturer for package assembly without requiring a separate step of applying die attach. During shipment or transport of the lead frame sheets having pre-applied die attach material, a sheet or film, such as a plastic material, may be applied to the surface of the lead frame sheet to protect the die attach material. The protective sheet or film is removed by the semiconductor device manufacturer and then a semiconductor device is attached to the lead frame sheet.

In some examples, the die attach film or adhesive that has been pre-applied to the lead frame sheet is activatable. The die attach material may not be sticky when applied to the lead frame sheet; however, when activated by heating or exposure to UV radiation, the die attach material becomes sticky and a semiconductor device may be mounted on the lead frame sheet. This allows the semiconductor device manufacturer to stage the lead frame sheet and then activate the die attach material when the process is ready to mount a semiconductor die.

FIG. 7 is a flowchart illustrating steps of an example process for manufacturing a semiconductor package. In step 701, a lead frame having a plurality of die attach pads is provided. Each die attach pad has a top surface with a pre-installed layer of die attach material. In some examples, the die attach material is die attach adhesive that is disposed within a cavity that has been etched into the top surface. A top surface of the die attach adhesive is coplanar with the top surface of the die attach pad. In other examples, the die attach material is die attach tape on the top surface. The die attach tape is cut to a size selected based upon the size of a semiconductor device to be mounted on the die attach pad.

In step 702, some lead frame examples require that a protective material be removed from the lead frame prior to adhering a semiconductor device.

In step 703, some die attach material examples require activating the die attach material using heat or UV energy in order to adhere a semiconductor device to a die attach pad.

In step 704, a semiconductor device is adhered to each die attach pad using the die attach material. When a die attach adhesive is used, a bottom surface of the semiconductor device may be coplanar with the top surface of the die attach adhesive and the top surface of the die attach pad. In other examples, when the die attach material is a die attach adhesive, the top surfaces of the die attach pads may include an additional portion of the die attach material that forms a ring or rim surrounding the cavity and the sides of the semiconductor device.

In step 705, wire bonds are attached from contacts on each semiconductor device to leads on the lead frame.

In step 706, at least a portion of the semiconductor devices, die attach pads, die adhesive material, wire bonds, and leads are covered with a mold compound. In some examples, the lead frame provided in step 701 may be premolded with mold compound pre-installed in spaces between conductive lead portions and die attach pad portions of the lead frame.

An example method of assembling a semiconductor package includes providing a lead frame having a plurality of die attach pads, wherein each die attach pad has a top surface with a pre-installed layer of die attach material. A semiconductor device is adhered to each die attach pad using the pre-installed die attach material. Wire bonds extending from contacts on each semiconductor device are attached to leads on the lead frame. At least a portion of the semiconductor devices, die attach pads, die adhesive material, wire bonds, and leads are covered with a mold compound.

In some examples, a cavity is etched into the top surface of each of the die attach pads on the lead frame. The pre-installed layer of die attach material is disposed within each of the cavities. The top surface of the die attach material is coplanar with the top surface of the die attach pad. The top surfaces of the die attach pads may include a portion of the die attach material surrounding the cavity.

The pre-installed layer of die attach material may be a die attach tape that has been cut to a size selected based upon the size of the semiconductor device.

The die attach material may be activated using heat or UV energy prior to adhering the semiconductor devices. A protective material may be attached to the lead frame and is removed prior to adhering the semiconductor devices.

An example method for manufacturing a lead frame comprises providing a lead frame material having a top surface and a bottom surface; etching the lead frame material to create a lead frame strip having a plurality of die attach pad regions and a plurality of conductive leads adjacent to each die attach pad region; etching the top surface of each die attach pad region to create a cavity; and depositing a die attach material in the cavity of each die attach pad region, wherein a top surface of the die attach material is coplanar with the top surface of the lead frame material. The amount of die attach material deposited in the cavity of each die attach pad is selected to prevent the die attach material from overflowing the die attach pad when a semiconductor die is mounted on the die attach pad using the die attach material. The amount of die attach material applied to the die attach pad is selected to minimize the height or thickness of a final semiconductor package.

The die attach material on the lead frame may be a die attach film that is cut to fit within the cavity.

In some examples, depositing the die attach material in the cavity includes spraying the die attach material into the cavity.

In some examples, depositing the die attach material in the cavity includes screen printing the die attach material into the cavity. The die attach material may be an ink residue that is printed into the cavity.

The die attach material on the lead frame may require activation using heat or UV energy prior to adhering a semiconductor device to the die attach pad region.

The process for manufacturing the lead frame may include applying a protective material to the lead frame sheet, wherein the protective material is configured for removal prior to adhering semiconductor devices to the die attach pads.

The process for manufacturing the lead frame may include depositing excess die attach material on the top surface of each die attach pad, wherein the excess die attach material forms a rim surrounding the cavity on each die attach pad.

An example lead frame sheet comprises a plurality of lead frame segments configured for singulation into separate units, where each lead frame segment having a die attach pad and a plurality of conductors. A cavity is formed in a top surface of each die attach pad. A die attach material is disposed within the cavity. The die attach material is adapted for mounting a semiconductor die on the die attach pad. A top surface of the die attach material is flush with the top surface of each die attach pad. A film applied to a top surface of the lead frame sheet. The protective film configured to protect the die attach material disposed within the cavities during transport of the lead frame sheet.

The lead frame may include a rim of additional die attach material on the top surface of the die attach pad and surrounding all sides of the cavity.

The lead frame sheet may include an amount of die attach material deposited in the cavity of each die attach pad that is selected to prevent the die attach material from overflowing the die attach pad when a semiconductor die is mounted on the die attach pad using the die attach material.

The lead frame sheet may further include a molding material applied between the plurality of die attach pads and the plurality of conductors, the molding material having a top surface and a bottom surface that are flush with a top surface and a bottom surface of the lead frame sheet.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. A method of assembling a semiconductor package, comprising:
providing a lead frame having a plurality of die attach pads, wherein each die attach pad has a top surface with a pre-installed layer of die attach material;
adhering a semiconductor device to each die attach pad using the pre-installed die attach material;
attaching wire bonds from contacts on each semiconductor device to leads on the lead frame; and
covering at least a portion of the semiconductor devices, die attach pads, die adhesive material, wire bonds, and leads with a mold compound.

2. The method of claim 1, wherein a cavity is etched into the top surface of each of the die attach pads on the lead frame, and wherein the pre-installed layer of die attach material is disposed within each of the cavities.

3. The method of claim 2, wherein a top surface of the die attach material is coplanar with the top surface of the die attach pad.

4. The method of claim 2, wherein the top surfaces of the die attach pads include a portion of the die attach material surrounding the cavity.

5. The method of claim 1, wherein the pre-installed layer of die attach material is a die attach tape that has been cut to a size selected based upon the size of the semiconductor device.

6. The method of claim 1, further comprising:
activating the die attach material using heat or UV energy prior to adhering the semiconductor devices.

7. The method of claim 1, further comprising:
removing a protective material from the lead frame prior to adhering the semiconductor devices.

8. A method for manufacturing a lead frame, comprising:
providing a lead frame material having a top surface and a bottom surface;
etching the lead frame material to create a lead frame strip having a plurality of die attach pad regions and a plurality of conductive leads adjacent to each die attach pad region;
etching the top surface of each die attach pad region to create a cavity; and
depositing a die attach material in the cavity of each die attach pad region, wherein a top surface of the die attach material is coplanar with the top surface of the lead frame material.

9. The method of claim 8, wherein the die attach material is a die attach film that is cut to fit within the cavity.

10. The method of claim 8, wherein depositing the die attach material in the cavity includes spraying the die attach material into the cavity.

11. The method of claim 8, wherein depositing the die attach material in the cavity includes screen printing the die attach material into the cavity.

12. The method of claim 8, wherein the die attach material is an ink residue printed into the cavity.

13. The method of claim 8, wherein the die attach material requires activation using heat or UV energy prior to adhering a semiconductor device to the die attach pad region.

14. The method of claim 8, further comprising:
applying a protective material to the lead frame sheet, wherein the protective material is configured for removal prior to adhering semiconductor devices to the die attach pads.

15. The method of claim 8, wherein depositing the die attach material further comprises:
depositing excess die attach material on the top surface of each die attach pad, wherein the excess die attach material forms a rim surrounding the cavity on each die attach pad.

16. The method of claim 8, wherein an amount of die attach material deposited in the cavity of each die attach pad is selected to prevent the die attach material from overflowing the die attach pad when a semiconductor die is mounted on the die attach pad using the die attach material.

17. A lead frame sheet, comprising:
a plurality of lead frame segments configured for singulation into separate units;
each lead frame segment having a die attach pad and a plurality of conductors;
a cavity formed in a top surface of each die attach pad;
a die attach material disposed within the cavity, the die attach material adapted for mounting a semiconductor die on the die attach pad, wherein a top surface of the die attach material is flush with the top surface of each die attach pad; and
a film applied to a top surface of the lead frame sheet, the protective film configured to protect the die attach material disposed within the cavities during transport of the lead frame sheet.

18. The lead frame sheet of claim 17, further comprising:
a rim of additional die attach material on the top surface of the die attach pad and surrounding all sides of the cavity.

19. The lead frame sheet of claim 17, wherein an amount of die attach material deposited in the cavity of each die attach pad is selected to prevent the die attach material from overflowing the die attach pad when a semiconductor die is mounted on the die attach pad using the die attach material.

20. The lead frame sheet of claim 17, further comprising:
a molding material applied between the plurality of die attach pads and the plurality of conductors, the molding material having a top surface and a bottom surface that are flush with a top surface and a bottom surface of the lead frame sheet.
